(19) United States
(12) Patent Application Publication
(10) Pub. No.: US 2014/0324518 A1
(43) Pub. Date: Oct. 30, 2014

(54) AUTOTAGGING BUSINESS PROCESSES

(71) Applicant: International Business Machines Corporation, Armonk, NY (US)

(72) Inventors: Haggai Roitman, Yokneam Elit (IL); Yossi Mesika, Afula (IL)

(21) Appl. No.: 14/331,238

(22) Filed: Jul. 15, 2014

Related U.S. Application Data
(63) Continuation-in-part of application No. 13/175,857, filed on Jul. 3, 2011.

(51) Int. Cl. G06Q 10/06; G06F 17/50

(52) U.S. Cl. CPC G06Q 10/0633; G06Q 10/067; G06F 17/509
USPC 705/7.27

(57) ABSTRACT

A method of autotagging business processes for monitoring analysis of an IT system within an organization is provided herein. The method includes the following stages: modeling an IT system associated with one or more business processes, into a model representing the business processes as process instances; tracking a flow of information entities throughout nodes located along the process instances; extracting, at each one of the nodes, tags associated with each one of the information entities flowing through the process instance; aggregating over time, the extracted tags being associated with its respective node and process instance; and visually representing the aggregated tags in association with its respective business processes, based on the model.

### CROSS-REFERENCE TO RELATED APPLICATIONS

This application is a continuation-in-part of U.S. patent application Ser. No. 13/175,587, filed Jul. 3, 2011.

### BACKGROUND

The present invention relates to the field of computerized business process management.

A business process or business method is a collection of related, structured activities or tasks that produce a specific service or product that may serve a particular goal for a particular customer or customers. It can often be visualized with a flowchart as a sequence of activities with interleaving decision points or with a process matrix as a sequence of activities with relevance rules based on data in the process.

As organizational business processes turn more complex, it becomes ever more challenging to track and analyze these processes within the organization. IT (Information Technology) systems that support business processes within an organization are characterized by a structured flow of information entities (e.g., documents) along various process instances, through which a variety of human observers may further carry out tasks in relation with the information entities, until the business process is completed.

In order to ease the handling of the business process, some metadata is associated with the information entities, partly to facilitate the tasks of the human observers and partially to provide visibility and control over the business process a whole. Currently, several software tools are known to mark the information entities as they flow from one instance to another along the business processes, in order to provide some monitoring capabilities that may be later be used by the management to analyze the business processes.

The Business Process Management Initiative (BPMI) is a non-profit organization that aims to promote the standardization of common business processes, as a means of furthering e-business and B2B development. BPMI's stated mission is “to promote and develop the use of Business Process Management (BPM) through the establishment of standards for process design, deployment, execution, maintenance, and optimization.” By doing so, BPMI intends to make it much easier for enterprises to interact and to further develop the global marketplace. Currently, e-business reflects the idiosyncratic ways that business processes work within an organization. There are, for example, different names for the same item, and incompatible processes across organizations. The goal of BPMI is to overcome these problems and make it possible for organizations to communicate more effectively and share not only data, but also applications.

The foregoing examples of the related art and limitations related therewith are intended to be illustrative and not exclusive. Other limitations of the related art will become apparent to those of skill in the art upon a reading of the specification and a study of the figures.

### SUMMARY

One aspect of the present invention provides a method of autotagging business processes for monitoring and analysis of an IT system within an organization. The method includes the following stages: modeling an IT system associated with one or more business processes, into a model representing the business processes as a process instances; tracking a flow of information entities throughout nodes located along the process instances; extracting, at each one of the nodes, metadata associated with each one of the information entities flowing through the process instance; aggregating over time, the extracted metadata being associated with its respective node and process instance; and finally, visually representing the aggregated metadata in association with its respective business processes, based on the model.

Other aspects of the invention may include a system arranged to execute the aforementioned method and a computer readable program configured to execute the aforementioned method. These, additional, and/or other aspects and/or advantages of the embodiments of the present invention are set forth in the detailed description which follows; possibly inferable from the detailed description; and/or learnable by practice of the embodiments of the present invention.

### BRIEF DESCRIPTION OF THE DRAWINGS

For a better understanding of embodiments of the invention and to show how the same may be carried into effect, reference will now be made, purely by way of example, to the accompanying drawings in which like numerals designate corresponding elements or sections throughout.

In the accompanying drawings:

FIG. 1 is a high level schematic block diagram illustrating an exemplary system according to some embodiments of the invention;

FIG. 2 is a high level flowchart illustrating an exemplary method according to some embodiments of the invention;

FIG. 3 is a diagram illustrating an aspect according to some embodiments of the invention; and

FIGS. 4A and 4b are further diagrams illustrating an aspect according to some embodiments of the present invention.

The drawings together with the following detailed description make apparent to those skilled in the art how the invention may be embodied in practice.

### DETAILED DESCRIPTION

Prior to setting forth the detailed description, it may be helpful to set forth definitions of certain terms that will be used hereinafter.

The term “business process” as used herein in this application refers to a collection of related, structured activities or tasks that produce a specific service or product for a particular customer or customers, or the organization itself. The business process may require the involvement of one or more human observers who carry out some of the tasks along the business process. The business process may be represented as a sequence of activities.

The term “tag” in the context of online computer systems, as used herein in this application refers a keyword or term assigned to an information entity (such as document or a computer file). This kind of metadata helps describe an item and allows it to be found again by browsing or searching. By aggregating tags one can visualize the data in an informal manner, such as a cloud of tags.

With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

Before explaining at least one embodiment of the invention in detail, it is to be understood that the invention is not limited in its application to the details of construction and the arrangement of the components set forth in the following description or illustrated in the drawings. The invention is applicable to other embodiments or of being practiced or carried out in various ways. Also, it is to be understood that the phraseology and terminology employed herein is for the purpose of description and should not be regarded as limiting.

The present invention, in embodiments thereof, uses metadata associated with information entities, to visually annotate (e.g. autotag) the business process along the flow. The metadata used for the visual representation may be either explicit or implicit and may refer to the content of the information entities, their transformation within the business processes, relationships to other information entities and human observers. Thus, embodiments of the present invention provide a method of (possibly informal) documenting this metadata during the lifecycle of the business process instantiations.

Embodiments of the present invention provide the ability to auto-tag business processes using the information entities metadata that flow within the process. The annotation or the tagging may be carried out, for example, by document's tags or by association to human observers that handled the documents during the process. Advantageously, the proposed auto tagging may help to discover hidden metadata about the process lifecycle and may be used for business process optimization, case management, and monitoring purposes.

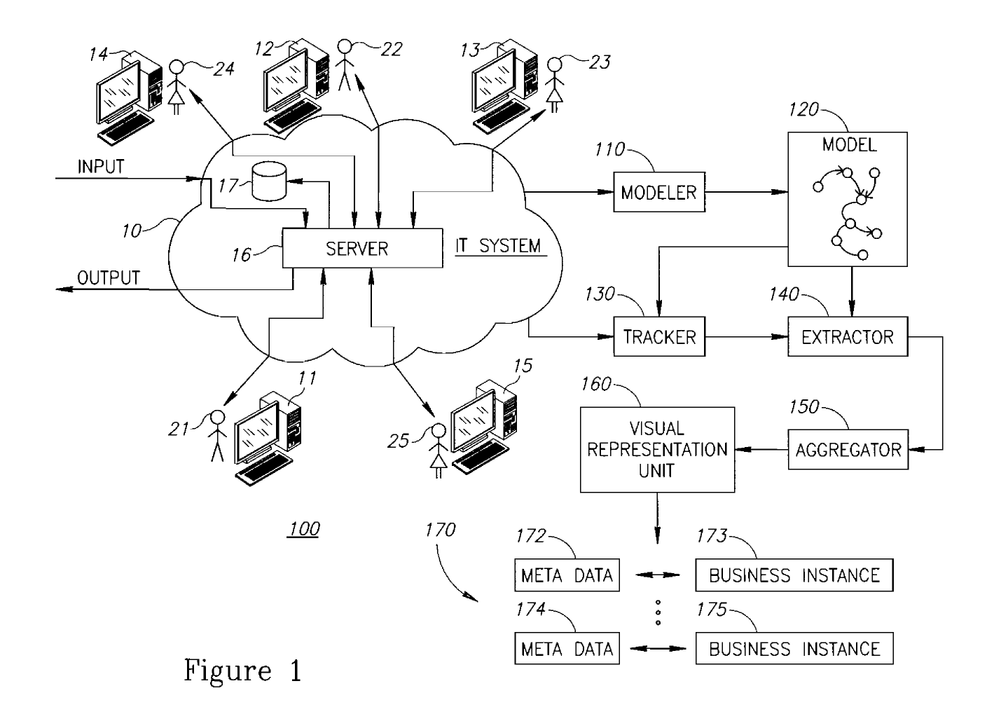

FIG. 1 is a high level schematic block diagram illustrating an exemplary system according to some embodiments of the invention. System 100 may include a modeler 110 and a tracker 130 in operative association with an organizational IT system 10 in which business processes take place. In a proposed non-limiting architecture, system 100 may further include an extractor 140, an aggregator 150 and a visual representation unit 160. IT system 10 may be any computerized system implemented, in a non-limiting example, by a server 16 and at least one database 17, wherein server 16 is connected to a plurality of networked computers 11-15. IT system 10 may be either connected to other systems via input/output or alternatively IT system 10 may be an isolated computerized system.

In operation, modeler 110 may be configured to model a computerized organizational IT system 10 associated with one or more business processes, into a model 120. Model 120 may represent the business processes as process instances. Tracker 130 may be configured to track a flow of information entities (not shown) throughout nodes located along process instance. Extractor 140 may be configured to extract, at each one of the nodes, metadata associated with each one of the information entities flowing through the process instance. Aggregator 150 may be configured to aggregate over time, the extracted metadata being associated with its respective node and process instance. Visual representation unit 160 may be configured to generate a visual representation 170 of the aggregated metadata 172 and 174 in association with its respective business processes 173 and 175, wherein the mapping is based on the model, and possibly over a timeline indicative of the business processes. Visual representation 170 may be presented over a display (not shown) either locally or remotely for monitoring and management purposes.

Model 120 may be based on business process modeling (BPM), as known in the art. BPM is often defined, in the field of systems engineering, as the activity of representing processes of a business, so that the processes may be analyzed, improved and/or otherwise handled manually or using a computer.

The business processes which may be represented by BPM may include, for example, purposes, strategies, infrastructure, organizational structures, trading practices, operational processes, and/or the like.—which are provided as text.

For illustration, a client may send a request to the business. The request may include a three-stage workflow. The first stage of the workflow may include an input; the input may include the user request details such as subject, field, type, etc. The second stage of the workflow may include a process such as data processing; the process may include the relevant examination of the request. The third and last stage of the workflow may be an output; the output may include the feedback which may be given to the client and/or for internal use of the business. In order to monitor and analyze the BPM using computerized means, translation of the BPM into a computer-readable BPM language may be required. Such BPM language may be the BPML (business process modeling language), the YAWL (yet another workflow language), and/or the like.

BPML is often defined as a meta-language based on an extensible markup language (XML), developed by BPMI. BPML may define an abstract model and a description of a generic process. As such, it may be used to define enterprise business processes, complex Web services and multiparty collaborations. The generic process may be viewed as a series of activities. An activity may represent as a component that performs a specific function. The activities may also be optionally composed into complex activities. The activities may be further executed within a hierarchical context which may be inherited from a “parent” generic process to a “child” generic process and/or an activity. This context may allow one or more activities to share the same properties. For illustration, a BPML code example is provided:

```
<process name=“Check”>
  <sequence>
    <operation>
      <participant name=“Clerk”/>
        <output message=“Feedback”>
            <assign from=“CustomerNumber” to=“ID” />
        </output>
          <input message=“Request”>
              <assign from=“Name” to=“CustomerName” />
          </input>
    </operation>
  </sequence>
</process>
```

A <process> element defines an activity and is the root element of a business process model. The process may consist of exactly one simple or complex activity and will end after this activity completed. The process element has a name attribute to indicate the name of the business process.

The elements between <operation> and </operation> include the specifics the activity. The </operation> element indicates the conclusion of the operation activity.

The <output> tag specifies what data should be outputted from the business process to the service. In this case, <assign from=“CustomerNumber” to=“ID”> indicates that the element ‘Customer Number’ is assigned to the value ‘ID,’ enabling the service to reference that value.

The <input> tag specifies what data in the output of a service should be used as input to the business process. The assign statement in the input section, that is <assign from=“NAME” to=“Customer Name”>, may indicate that the service returned a value for the “NAME”. In addition, this value will be copied to “Customer Name” in the process data, to be available for other services to use. Not all services require input or produce output. Even if a service does produce output, the business process designer may not require using any or all of the data returned by a service. Output assignments transpire before the service executes. Input mappings transpire after the service has completed.

YAWL is often defined as a workflow language based on workflow patterns. The language is supported by a software system that includes an execution engine, a graphical editor and a work-list handler. YAWL is an XML-based language. The data perspective in YAWL is captured through the use of XML Schema, XPath and XQuery, which are further discussed below. An XML Schema is often defined as a description of a type of XML document, typically expressed in terms of constraints on the structure and content of documents of that type, above and beyond the basic syntactical constraints imposed by XML itself. XPath is often defined as a query language for selecting nodes from an XML document. In addition, XPath may be used to compute values (e.g. strings, numbers, and/or Boolean values) from the content of XML document. XQuery, in turn, is often defined as a querying and functional programming language that is designed to query and transform collections of structured and unstructured data, usually in the form of XML, text and/or specific extensions for other data formats (JSON, binary, etc.). YAWL offers comprehensive support for the control-flow patterns, resource patterns, and dynamic workflows. Tasks in YAWL can be mapped to human participants, Web services, external applications and/or to Java classes.

Modeler 110 may be a software module configured to receive, as input, textual information about one or more business process, and convert this information, according to the syntax of BPML, YAWL or a different business process model language, into model 120. Model 120 may represent the business processes as process instances, similar to a class and an instance in object-oriented programming (OOP) languages.

Tracker 130 may be a software module configured to track a flow of information entities (not shown), each represented textually, by a character string. As known in the field of data modeling, an (information) entity may be one or more units of data that can be classified and have stated relationships to other entities. Continuing the previous OOP analogy, information entities may be similar to properties of an object. In addition, tracker 130 may be an outsource function or an extension function of the process, similar to a helper class or a class extension in OOP.

Tracker 130 may be set to run by a user request and/or automatically by modeler 110. The information entities may be tracked throughout nodes located along a process instance. The information entities may have associated metadata relevant to each node of the process instance. In the OOP analogy, metadata may be similar to values that are assigned to properties. The input of tracker 130 may be a certain database; tracker 130 may track keywords using regular expressions (RegEx's), a search engine and/or the like, as known in the art. The output of tracker 130 may be a collection (e.g. array, list, etc.) of the information entities with optional additional fields of their location, “parent” business process, process instance and/or a relative node.

The information entities may be represented by a Web services description language such as WSDL, the Web Ontology Language for Services (OWL-S), and/or the like. WSDL is often defined as an XML based language used to describe the services offered by a business, and provides a way for other businesses to access those services by the use of computerized devices. WSDL may be used in combination with simple object access protocol (SOAP) and/or XML schema in order to provide Web services over the internet. SOAP is often defined as a software protocol which allows a program running in one kind of operating system to communicate with a program in the same or different kind of operating system. The communication may be made using Hypertext Transfer Protocol (HTTP) and its XML in order to exchange the information between the two operating systems.

OWL-S is often defined as ontology Web language (OWL)-based Web service ontology. The OWL-S may provide Web services with a core set of markup language, constructs for describing the properties and capabilities of Web services, computer-interpretable form. OWL-S markup of Web services may facilitate the automation of Web services such as Web service tasks, execution, composition and interoperation.

Extractor 140 may be a software module configured to extract the associated metadata with respect to each one of the information entities flowing through the process instance. The input to extractor 140 may be the output of tracker 130; extractor 140 may pull out data using an extract method, as known in the art. The output of extractor 140 may be a collection (e.g. array, list, etc.) of the extracted data, the information entity that the extracted data is attributed to, “parent” business process, process instance and/or a respective node.

Aggregator 150 may be a software module configured to aggregate, over time, the extracted metadata being associated with its respective node and/or process instance. The input of aggregator 150 may be the output of extractor 140. The output of aggregator 150 may be a collection of information entities with optional additional fields of ranking, “parent” business process, process instance and/or a respective node. The output of aggregator 150 may be stored in a non-transient memory. This may further enable the ranking of the extracted metadata in factors such as frequency, frequency per time, frequency per a respective node and/or process instance, etc.

Visual representation unit 160 may be a software module configured to generate a visual representation 170, such as a diagram of the information entities with their perspective ranking. Visual representation unit 160 may generate the visual representation through BPM design software such as business process model and notation (BPMN), as known in the art, which provides a graphical notation for specifying business processes, based on a flowcharting technique. BPMN may enable business process management, for both technical users and business users, by providing a notation that may be intuitive to business users, yet able to represent complex process semantics. BPMN further provides a standard notation which may be understandable by business administration specialists who create and refine the processes, technical developers who responsible for implementing them, and/or the business managers who monitor and manage them. Consequently, BPMN may enable to close the gap which frequently exists between business process design and implementation.

The input of visual representation unit 160 may be the output of aggregator 150; visual representation unit 160 may generate a diagram of the information entities with their perspective ranking, the diagram may further include a respect of the information entities to the “parent” business process, process instance and/or a respect node. The output of visual representation unit 160 may be visual representation 170 and/or a list of information entities, their ranking, “parent” business process, process instance and/or a respective node.

Visual representation 170 may include aggregated metadata 172, 174 and business processes 173, 175. Aggregated metadata 172, 174 may include the output metadata of the aggregating process executed by aggregator 150. Business processes 173, 175 may include all the selected business processes as they were determined in the definition of a business processes modeling. Visual representation 170 may be based on a designated model, and may be a timeline indicative of the business processes. Visual representation 170 may be presented on a computer display, either locally or remotely, for monitoring and management purposes.

Consistent with some embodiments of the present invention, IT system 10 may be further associated with human observers 21-25. In order for IT system 10 to associate with human observers 21-25, IT system 10 may use a business process modeling language such as business process execution language (BPEL), as known in the art. BPEL is often defined as an XML-based language that enables task-sharing in a distributed computing or grid computing environment. BPEL may be used to convert business visions into viewable processes that can be run and displayed on computers. BPEL standardizes how business processes flow and describes the process logic for the involved Web services that may be invoked. BPEL4People, as known in the art, is an extension of BPEL; BPEL4People extends BPEL from orchestration of Web services alone to orchestration of role-based human activities as well. BPEL4people may further enable the association of human tasks and/or records, in the business process. All elements and attributes introduced in this extension are made available to both BPEL executable processes and abstract processes. This extension introduces a set of elements and attributes to cover different complex human interaction patterns, such as separation of duties, which are not defined as first-class elements.

Consistent with some embodiments of the present invention, modeler 110 may be further configured to yield a model that comprises at least one directed acyclic graph defined by nodes and edges, wherein the process instance is a flow within the graph along a plurality of nodes wherein the edges represent transitions from one node to another.

Consistent with some embodiments of the present invention, IT system 10 may be associated with an organization that carries out a plurality of processes and sub processes, some of which involve clients, human observers (such as employees of the organization) and client-employees interaction. Specifically, respective metadata may include at least one of the following: client interaction with the organization, internal operations within the organization, external action with the organization, entities other than the organization.

Consistent with some embodiments of the present invention, visual representation unit 160 may further be configured to generate a visual representation that indicates predefined weighing of a priority of each portion of the extracted metadata. The visual representation may be created as a design pattern such as a list, a tag cloud, and/or the like. The visual representation may include one or more tags representing the flowing information entities. Aggregator 150 may accumulate the frequency of each tag in a respective node and/or process instance. Each one of the tags may include a ranking which is based on its frequency, as apparent from the output of aggregator 150.

A tag cloud, as known in the art, is a visual representation for text data, typically used to depict keyword metadata (tags) on websites, or to visualize free form text. Tags are usually single words or multi-word terms, and the importance of each tag is shown with font size and/or color. This format is useful for quickly perceiving the most prominent tag and, optionally, for locating a tag alphabetically to determine its relative prominence (frequency).

Consistent with some embodiments of the present invention, visual representation unit 160 may be further configured to generate a visual representation indicative of transformations of at least one of the following: metadata, information entity, priority, wherein the transformation is carried out along the flow of each business process. This may provide further insight on the dynamic nature of the data, or information entities of all kinds along the business processes. For illustration, in a preceding node a certain term may appear in many messages within the node. As the frequency of the certain term increases, the greater the weight that a tag of the certain term may have in that particular node. Meanwhile, in the next node connected to this node, this certain term may be used less frequently, so a tag of the certain term in the next node may have a lower weight. By displaying the tags over both nodes in the visual representation, human observers 21-25 may view the certain term transformation through the business process.

Consistent with some embodiments of the present invention, the visual representation unit may further be configured to generate a visual representation that allows navigation through the business processes, indicating aspects of the metadata responsive to user selection. For example, the navigable representation may be in the form of a tag cloud that provides further visual information responsive to user selection. A user may click on one of the tags or the human observers and in response, interrelations between tags, human observers, processes and the like.

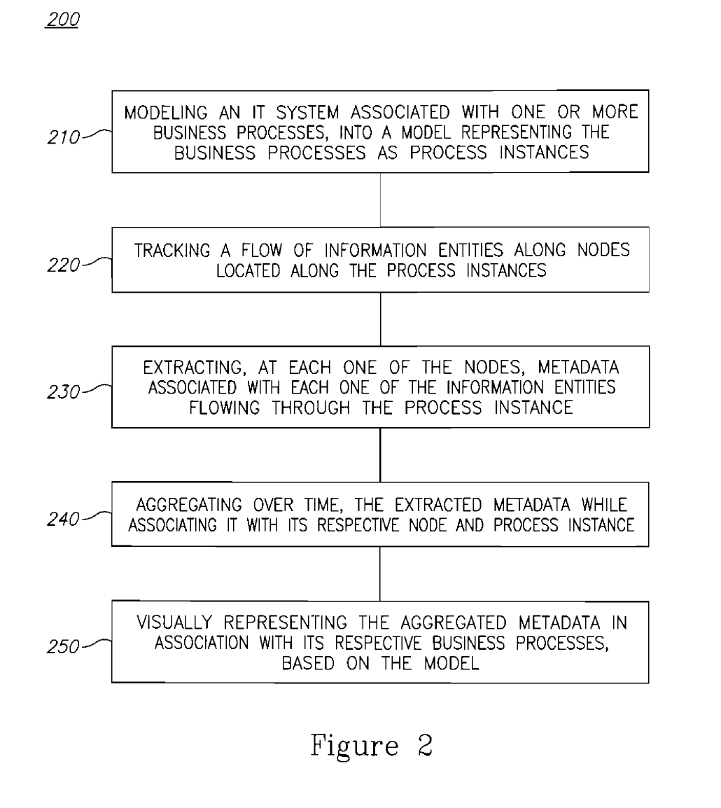

FIG. 2 is a high level flowchart illustrating a method 200 according to some embodiments of the invention. It is understood that method 200 may not be necessarily implemented by the aforementioned architecture of system 100. However, for the sake of clarity, the following steps of method 200 are described in conjunction with components of system 100. Method 200 may start with a step of modeling 210 possibly via modeler 110 an IT system associated with one or more business processes, into a model 120 representing the business processes as process instances. Method 200 then goes on the step of tracking 220 possibly via tracker 130 a flow of information entities along nodes located along the process instances. Then, the method proceeds to a step of extracting 230, possibly via extractor 140 at each one of the nodes, metadata associated with each one of the information entities flowing through the process instance. Then, in an aggregating step 240, the method goes on to aggregating over time, possibly via aggregator 150, the extracted metadata while associating it with its respective node and process instance. Finally, method 200 proceed to the step of visually representing 250, possibly via a display or a visual representation unit 160 the aggregated metadata in association with its respective business processes, based on the model, possibly over a timeline.

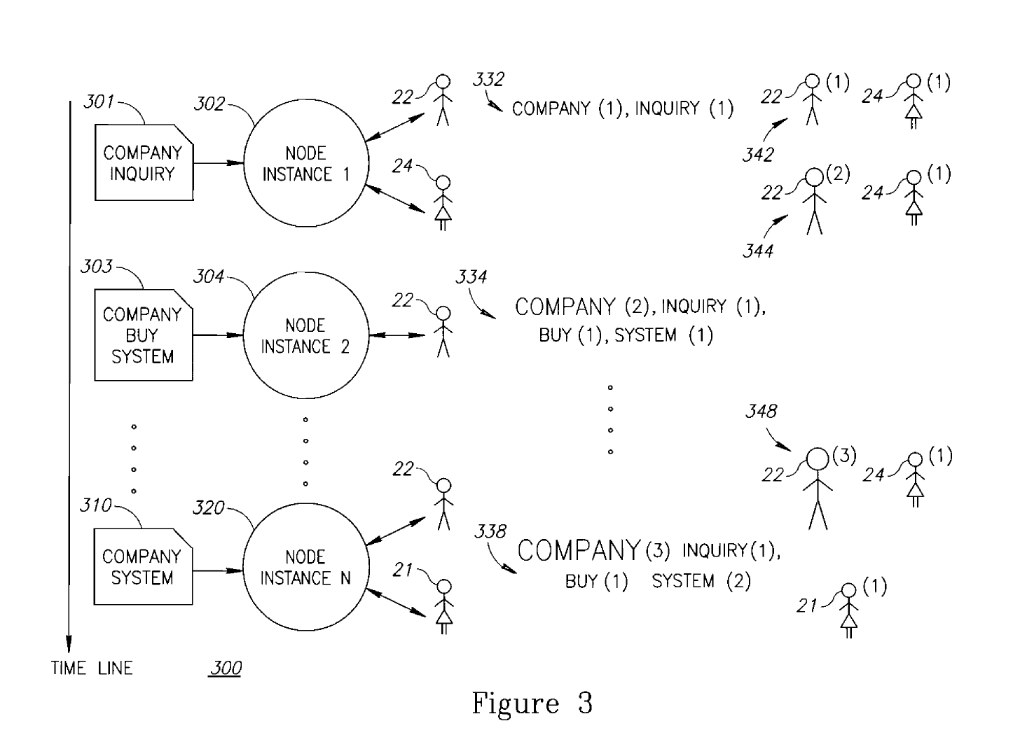

FIG. 3 is a diagram illustrating an aspect according to some embodiments of the invention. a business process in modeled as a process instances that may include nodes 302, 304 . . . 320. Each one of the nodes is respectively associated with metadata 301, 303 . . . 310 indicative in turn of respective information entities (not shown). The metadata may indicate the type of operation carried out at the node (e.g., inquiry, buy) or an organization associated with the operation (e.g., name of company). Additionally, the nodes may further be associated with human observers 21, 22, and 24. After carrying out the stages of the method according to embodiments of the present invention, respective visual representations 332, 334 . . . 338 of the nodes may be presented to a user. In one form, a tag cloud indicative of the accumulated occurrences of the metadata in each node may be presented, with the size indicative of the occurrences. Additionally, the human observers may also be presented similarly to the metadata tags as clouds 342, 344 and 348 with indications as to occurrences by explicit numbers or by size.

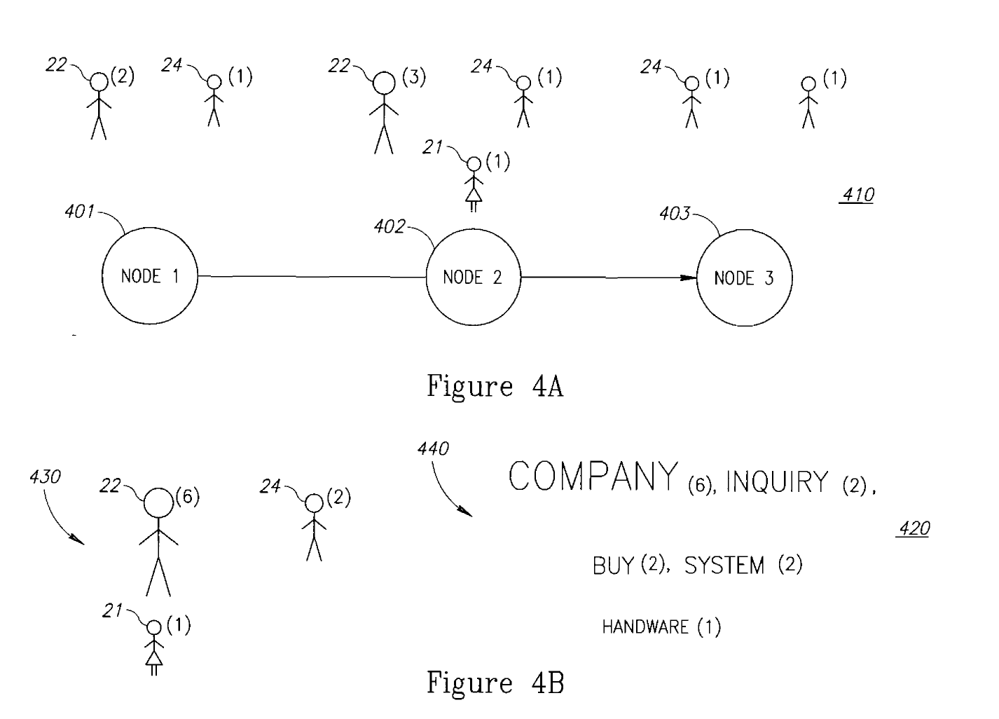

FIG. 4A is another diagram illustrating a modeled flow 410 of process or processes shown as nodes 401-403, each one of the nodes being associated with human observers 21, 22, and 24. FIG. 4B illustrates the two aforementioned forms of visual representation 420 discussed above for the aggregated metadata. Tag cloud 440 shows the tags extracted and aggregated along flow 410 in which size represents occurrence. Additionally and alternatively, the occurrence may also be put in parentheses. Human observers' cloud 430 is also shown. Here, too, size represents occurrences. These clouds, as explained above may be interactive by nature, allowing a user to click on some of the tags/human observers icons thus revealing types of relationships between them and further information illustrative of the nature of data flow within the organization. For example, when a user clicks on some tag in the cloud, the system can show all related process instances from which the user can further zoom into some specific related node.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Program code embodied on a computer readable medium may be transmitted using any appropriate medium, including but not limited to wireless, wire-line, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described above with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a hardware processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The aforementioned flowchart and diagrams illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

In the above description, an embodiment is an example or implementation of the inventions. The various appearances of “one embodiment,” “an embodiment” or “some embodiments” do not necessarily all refer to the same embodiments.

Although various features of the invention may be described in the context of a single embodiment, the features may also be provided separately or in any suitable combination. Conversely, although the invention may be described herein in the context of separate embodiments for clarity, the invention may also be implemented in a single embodiment.

Reference in the specification to “some embodiments”, “an embodiment”, “one embodiment” or “other embodiments” means that a particular feature, structure, or characteristic described in connection with the embodiments is included in at least some embodiments, but not necessarily all embodiments, of the inventions.

It is to be understood that the phraseology and terminology employed herein is not to be construed as limiting and are for descriptive purpose only.

The principles and uses of the teachings of the present invention may be better understood with reference to the accompanying description, figures and examples.

It is to be understood that the details set forth herein do not construe a limitation to an application of the invention.

Furthermore, it is to be understood that the invention can be carried out or practiced in various ways and that the invention can be implemented in embodiments other than the ones outlined in the description above.

It is to be understood that the terms “including”, “comprising”, “consisting” and grammatical variants thereof do not preclude the addition of one or more components, features, steps, or integers or groups thereof and that the terms are to be construed as specifying components, features, steps or integers.

If the specification or claims refer to “an additional” element, that does not preclude there being more than one of the additional element.

It is to be understood that where the claims or specification refer to “a” or “an” element, such reference is not be construed that there is only one of that element.

It is to be understood that where the specification states that a component, feature, structure, or characteristic “may”, “might”, “can” or “could” be included, that particular component, feature, structure, or characteristic is not required to be included.

Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described.

Methods of the present invention may be implemented by performing or completing manually, automatically, or a combination thereof, selected steps or tasks.

The descriptions, examples, methods and materials presented in the claims and the specification are not to be construed as limiting but rather as illustrative only.

Meanings of technical and scientific terms used herein are to be commonly understood as by one of ordinary skill in the art to which the invention belongs, unless otherwise defined.

The present invention may be implemented in the testing or practice with methods and materials equivalent or similar to those described herein.

Any publications, including patents, patent applications and articles, referenced or mentioned in this specification are herein incorporated in their entirety into the specification, to the same extent as if each individual publication was specifically and individually indicated to be incorporated herein. In addition, citation or identification of any reference in the description of some embodiments of the invention shall not be construed as an admission that such reference is available as prior art to the present invention.

While the invention has been described with respect to a limited number of embodiments, these should not be construed as limitations on the scope of the invention, but rather as exemplifications of some of the preferred embodiments. Other possible variations, modifications, and applications are also within the scope of the invention. Accordingly, the scope of the invention should not be limited by what has thus far been described, but by the appended claims and their legal equivalents.

What is claimed is:

1. A method comprising operating at least one hardware processor for:
modeling an IT system that includes a plurality of networked computers and further associated with one or more business processes, into a model representing the business processes as process instances;
tracking a flow of information entities along nodes located along the process instances;
extracting, at each one of the nodes, tags associated with each one of the information entities flowing through the process instance;
aggregating over time, the extracted tags while associating them with their respective node and process instance; and
visually representing the aggregated tags over a display, in association with its respective business processes, based on the model.

2. The method according to claim 1, wherein the IT system is further associated with human observers, and wherein the aggregating further includes associating the human observers with their respective nodes or process instances.

3. The method according to claim 1, wherein the model comprises at least one directed acyclic graph defined by nodes and edges, wherein the process instance represents a specific flow through a set of nodes and wherein the edges represent transitions from one node to another.

4. The method according to claim 1, wherein the IT system is associated with an organization.

5. The method according to claim 1, wherein the visual representation is selected such that it indicates predefined weighing of a priority of each portion of the extracted tags.

6. The method according to claim 1, wherein the visual representation is indicative of transformations of at least one of: tags, information entity, priority, along the flow of each business process.

7. The method according to claim 1, wherein the visual representation allows navigation through the business processes, indicating aspects of the tags responsive to user selection.

8. A system comprising at least one hardware processor configured to execute instructions which comprise:
a modeler configured to model an IT system that includes a plurality of networked computers and further associated with one or more business processes, into a model representing the business processes as process instances;
a tracker configured to track a flow of information entities along nodes located along the process instance;
an extractor configured to extract, at each one of the nodes, tags associated with each one of the information entities flowing through the process instance;
an aggregator configured to aggregate over time, the extracted tags being associated with their respective node and process instance; and
a visual representation unit configured to visually represent the aggregated tags over a display in association with their respective business processes, based on the model.

9. The system according to claim 8, wherein the IT system is further associated with human observers, and wherein the aggregator is further configured to associate the human observers with their respective node or process instances.

10. The system according to claim 8, wherein the modeler is further configured to yield a model that comprises at least one directed acyclic graph defined by nodes and edges, the process instance represent a specific flow through a set of nodes and wherein the edges represent transitions from one node to another.

11. The system according to claim 8, wherein the IT system is associated with an organization.

12. The system according to claim 8, wherein the visual representation unit is further configured to generate a visual representation that indicates predefined weighing of a priority of each portion of the extracted tags.

13. The system according to claim 8, wherein the visual representation unit is further configured to generate a visual representation indicative of transformations of at least one of: tags, information entity, priority, along the flow of each business process.

14. The system according to claim 8, wherein the visual representation unit is further configured to generate a visual representation that allows navigation through the business processes, indicating aspects of the tags responsive to user selection.

15. A computer program product, the computer program product comprising:
a computer readable storage medium having computer readable program embodied therewith, the computer readable program comprising:
computer readable program configured to model an IT system that includes a plurality of networked computers and further associated with one or more business processes, into a model representing the business processes as process instances;
computer readable program configured to track a flow of information entities along nodes located along the process instances;
computer readable program configured to extract, at each one of the nodes, tags associated with each one of the information entities flowing through the process instance;
computer readable program configured to aggregate over time, the extracted tags being associated with their respective node and process instance; and
computer readable program configured to visually represent the aggregated tags over a display, in association with their respective business processes, based on the model.

16. The computer program product according to claim 15, wherein the IT system is further associated with human observers, and wherein the aggregator is further configured to associate the human observers with their respective process instances.

17. The computer program product according to claim 15, wherein the model comprises at least one directed acyclic graph defined by nodes and edges, wherein the nodes represent the process instances and the edges represent transitions from one process instance to another.

18. The computer program product according to claim 15, wherein the IT system is associated with an organization.

19. The computer program product according to claim 15, wherein the visual representation indicates predefined weighing of a priority of each portion of the extracted tags.

20. The computer program product according to claim 15, wherein the visual representation is of transformations of at least one of: tags, information entity, and priority, all along the flow of each business process.
